(19) United States
(12) Patent Application Publication
(10) Pub. No.: US 2021/0167092 A1
(43) Pub. Date: Jun. 3, 2021

(54) Array Substrate, Display Panel, and Display Device

(71) Applicant: WUHAN CHINA STAR OPTOELECTRONICS TECHNOLOGY CO., LTD, Wuhan, Hubei (CN)

(72) Inventor: Zhihao CAO, Wuhan, Hubei (CN)

(21) Appl. No.: 16/649,715

(22) PCT Filed: Dec. 12, 2019
(86) PCT No.: PCT/CN2019/124955

§ 371 Date: Mar. 23, 2020

(30) Foreign Application Priority Data
Dec. 3, 2019 (CN) 201911217707.7

(51) Int. Cl. H01L 27/12

(52) U.S. Cl. CPC H01L 27/124; H01L 27/1248

(57) ABSTRACT

An array substrate, a display panel, and a display device are provided. The array substrate includes a wiring region and a thin film transistor (TFT) device functional region. The wiring region includes a gate electrode layer, a dielectric layer disposed on the gate electrode layer, and a data wire layer disposed on the dielectric layer. A plurality of via holes are defined on the dielectric layer. The data wire layer is connected to the gate electrode layer through the plurality of via holes. A data wire formed from the data wire layer and a gate wire formed from the gate wire electrode layer constitute a parallel connection structure at positions of the plurality of via holes.

### CROSS REFERENCE TO RELATED APPLICATIONS

This application claims priority of Chinese patent application No. CN201911217707.7 filed on Dec. 3, 2019 with the National Intellectual Property Administration, titled “Array substrate, display panel, and display device”, which is incorporated by reference in the present application in its entirety.

### FIELD OF INVENTION

The present disclosure relates to the field of display technology, and particularly relates to an array substrate, a display panel, and a display device.

### BACKGROUND OF INVENTION

With development of display technology, a proportion of large-sized products using low-temperature polycrystalline silicon (LTPS) technology is increasingly higher. In circuits of the LTPS technology, requirements on impedance of wires are high, particularly for gate wires. The gate wires control a row of devices in the circuits, and there is a certain impedance on the gate wires. For small-sized panels, gate wires are short, and their impedance has little influence on the circuits. However, when sizes of panels get bigger, gate wires become longer therewith, so resistance of the gate wires will have a certain influence on the circuits. Therefore, an effect of resistive divider will be increasingly obvious. That is, when a driving electric current is transmitted to devices located further along gate wires, a driving voltage is correspondingly reduced. When the driving voltage is reduced to a certain value, this may cause the devices to not be able to turn on normally.

Therefore, in order to prevent the situation mentioned above from occurring, a new design plan is urgently required to solve deficiencies existing in the prior art.

### SUMMARY OF INVENTION

The purpose of the present disclosure is that embodiments of the present disclosure provide an array substrate, a display panel, and a display device, which enables to effectively solve the problem that electric resistance of the gate wires is too large.

According to one aspect of the present disclosure, an embodiment of the present disclosure provides an array substrate. The array substrate includes a wiring region and a thin film transistor (TFT) device functional region. The wiring region includes a gate wire layer, a dielectric layer disposed on the gate wire layer, and a data wire layer disposed on the dielectric layer. A plurality of via holes are disposed on the dielectric layer. The data wire layer is connected to the gate wire layer through the plurality of via holes. A data wire formed from the data wire layer and a gate wire formed from the gate electrode layer constitute a parallel connection structure at positions of the plurality of via holes.

Furthermore, a plurality of protruding sections are formed on the data wire layer, the plurality of protruding sections are connected to a first gate electrode layer through the plurality of via holes, and the plurality of protruding sections protrude from the first gate electrode layer along a width direction of the first gate electrode layer.

Furthermore, a region where each of the protruding sections is located corresponds to a region where each of the via holes is located.

Furthermore, a distance of the plurality of protruding sections protruding from the first gate electrode layer is not greater than 15 μm.

Furthermore, a resistance value of the parallel connection structure is less than a resistance value of the gate wire.

Furthermore, the TFT device functional region includes a source electrode layer, a drain electrode layer, and an active layer, and the active layer is disposed beneath the gate electrode layer.

Furthermore, a vertical projection of the plurality of via holes on the gate electrode layer and a vertical projection of the source electrode layer and the drain electrode layer on the gate electrode layer are spaced apart.

According to another aspect of the present disclosure, an embodiment of the present disclosure further provides a display panel. The display panel includes the array substrate mentioned above.

According to a further aspect of the present disclosure, an embodiment of the present disclosure further provides a display device. The display device includes the display panel mentioned above.

The advantage of the present disclosure is that in the present disclosure, the data wire and the gate wire are set as parallel connection at a set location, and in a situation of not affecting a channel width of the active layer, the protruding sections are disposed in a spaced-apart manner on the original gate wire to reduce resistance of the gate wire, thereby effectively preventing the problem of excessive resistance of the gate wire due to overly large sizes of products, thus improving performance of the products.

### DESCRIPTION OF DRAWINGS

To more clearly illustrate the technical solutions of the embodiments of the present disclosure, the accompanying figures of the present disclosure will be described in brief. Obviously, the accompanying figures described below are only part of the embodiments of the present disclosure, from which those skilled in the art can derive further figures without making any inventive efforts.

FIG. 1 is a structural schematic diagram of an array substrate provided by an embodiment of the present disclosure.

FIG. 2 is a top schematic view of the array substrate provided by the embodiment of the present disclosure.

FIG. 3 is an equivalent schematic diagram of a data wire and a gate wire being in parallel connection provided by an embodiment of the present disclosure.

FIG. 4 is a structural schematic diagram of a display panel provided by an embodiment of the present disclosure.

FIG. 5 is a structural schematic diagram of a display device provided by an embodiment of the present disclosure.

### DETAILED DESCRIPTION OF PREFERRED EMBODIMENTS

The technical solutions in the embodiments of the present disclosure are clearly and completely described in the following with reference to the accompanying drawings in the embodiments of the present disclosure. Obviously, the described embodiments are only part of the embodiments of the present disclosure, but are not all embodiments of the present disclosure. All other embodiments obtained by those skilled in the art based on the embodiments of the present disclosure without creative efforts are within the scope of the present disclosure.

In the description of the present disclosure, it is to be understood that the orientation or positional relationship indicated by the terms “center”, “longitudinal”, “transverse”, “length”, “width”, “thickness”, “upper”, “lower”, “front”, “rear”, “left”, “right”, “vertical”, “horizontal”, “top”, “bottom”, “inside”, “outside”, “clockwise”, “counterclockwise” etc. is based on the orientation or positional relationship shown in the accompanying figures, which is merely for the convenience for describing of the present disclosure and for the simplification of the description, and is not intended to indicate or imply that the indicated devices or elements have a specific orientation or is constructed and operated in a specific orientation. Therefore, it should not be understood as a limitation on the present disclosure.

Moreover, the terms “first” and “second” are used for descriptive purposes only and are not to be understood as indicating or implying relative importance or implicitly indicating the number of the indicated technical characteristics. Therefore, the characteristics defined by “first” or “second” may include one or more of the described characteristics either explicitly or implicitly. In the description of the present disclosure, the meaning of “a plurality” is two or more unless clearly and specifically defined otherwise.

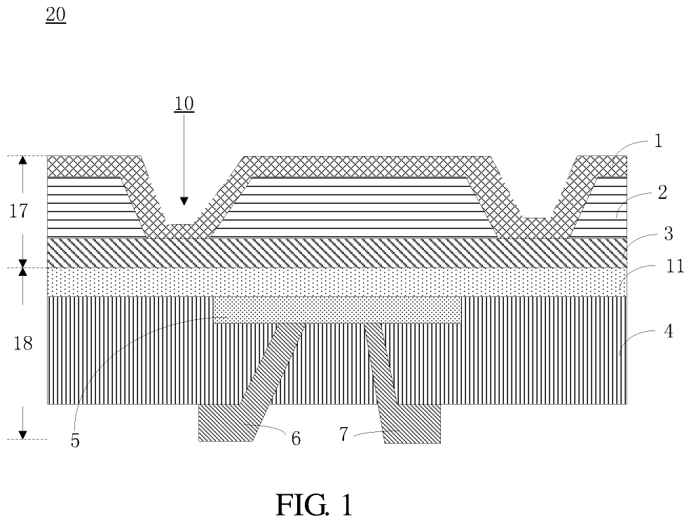

Illustrated in FIG. 1 is a structural schematic diagram of an array substrate provided by the present disclosure. The array substrate includes a wiring region 17, a thin film transistor (TFT) device functional region 18, a gate insulating layer 11, and an insulating layer 4.

The wiring region 17 includes a dielectric layer 2, a data wire layer 1, and a gate electrode layer 3.

The TFT device functional region 18 includes an active layer 5, a source electrode layer 7, and a drain electrode layer 6.

Specifically, a thickness of the insulating layer 4 is 200 nm, and a material of the insulating layer 4 can be Si₃N₄.

The active layer 5 is disposed on the insulating layer 4. As illustrated in FIG. 1, the active layer 5 in FIG. 1 is a patterned active layer. A thickness of the active layer is 50 nm. A material of the active layer is a metal-oxide semiconductor material. In this embodiment, an indium gallium zinc oxide (IGZO) material is used to manufacture the active layer. The material has advantages such as high mobility, suitability for large-area production, and conduciveness for switching from amorphous silicon (a-Si) process. Of course, materials of the active layer are not limited herein, and indium gallium selenium oxide (IGSO) can also be used.

Furthermore, the active layer includes a channel region, a source electrode contact region and a drain electrode contact region separately located on two sides of the channel region, and lightly doped regions located between the channel region and the source electrode contact region, and between the channel region and the drain electrode contact region. Furthermore, the channel region is a path for carrier flow.

A source electrode layer 7 and a drain electrode layer 6 are disposed on a bottom of the insulating layer 4. Thicknesses of the source electrode layer 7 and the drain electrode layer 6 are 200 nm. In this embodiment, by performing patterning operation on the source electrode layer 7 and the drain electrode layer 6, the source electrode layer 7 and the drain electrode layer 6 disposed in a spaced-apart manner are formed. The source electrode layer 7 and the drain electrode layer 6 respectively contact the source electrode contact region and the drain electrode contact region of the active layer 5 by a first via hole and a second via hole defined on the insulating layer 4.

The gate insulating layer 11 is disposed on the active layer 5, and a thickness of the gate insulating layer 11 is 150 nm. A material of the gate insulating layer 11 is SiO₂, but it is not limited thereto; for example, it can be Si₃N₄ or Al₂O₃.

The gate electrode layer 3 is disposed on the gate insulating layer 11. A material of the gate electrode layer 3 is a metal material, and specifically is an alloy of one or more of Mo, Al, Cu, or Ti. A thickness of the gate electrode layer 3 can be 200 nm.

The dielectric layer 2 is disposed on the gate electrode layer. The dielectric layer 2 is made of a silica material or a silicon nitride material.

The data wire layer 1 is disposed on the dielectric layer 2. A material of the data wire layer 1 is made of a metal material, and specifically, it is an alloy of one or more of Mo, Al, Cu, or Ti, but it is not limited thereto.

Furthermore, a plurality of via holes 10 are defined on the dielectric layer 2. The data wire layer 1 is connected to the gate electrode layer 3 through the via holes 10. The data wire layer 1 and the gate electrode layer 3 are made of metal materials. A data wire formed from the data wire layer 1 and a gate wire formed from the gate electrode layer 3 constitute a parallel connection structure at positions of the via holes 10. A resistance value of the parallel connection structure is less than a resistance value of the gate wire.

As illustrated in FIG. 3, the data wire and the gate wire constitute the parallel connection structure at the positions of the via holes. The resistance value of the parallel connection structure, which is a first gate electrode resistor 12 and a data resistor 13 in parallel connection and then connected to a second gate resistor 14 in series connection in FIG. 3, is less than a resistance value of an original gate wire, which is the first gate electrode resistor 12 and the second gate resistor 14 in series connection. Through such design, the gate wire is optimized to reduce the resistance value without affecting the devices, thereby ensuring an effect of low-temperature polycrystalline-silicon technology on large-sized products.

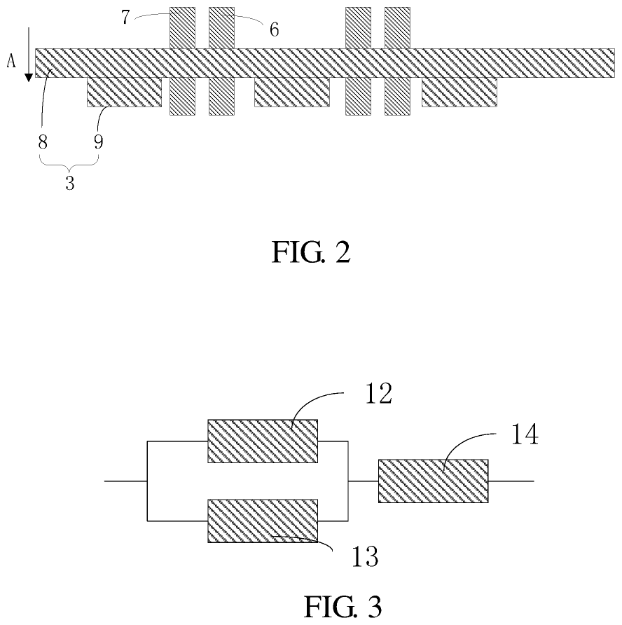

With reference to FIG. 2, the gate electrode layer includes a first gate electrode layer 8 and a plurality of protruding sections 9. The first gate electrode layer 8 and the protruding sections 9 are disposed on a same layer. The protruding sections 9 protrude from the first gate electrode layer along a width direction of the first gate electrode layer (a direction of arrow A illustrated in FIG. 2).

Regions where each of the protruding sections 9 are located correspond to regions where each of the via holes 10 are located. A vertical projection of the via holes 10 on the gate electrode layer 3 and a vertical projection of the source electrode layer 7 and the drain electrode layer 6 on the gate electrode layer 3 are spaced apart. Therefore, this will not affect a channel width to length ratio of the active layer 5.

Based on an original first gate electrode layer, the present disclosure adds the protruding sections 9 to form the parallel connection structure to increase a width of part of the region of the gate wire (gate electrode layer 3), which is equivalent to increasing a cross-sectional area of the gate wire. According to a formula of electrical resistance values, it can be understood that an electrical resistance value is obtained from a product value of a resistivity and a length of a resistor divided by a cross-sectional area of the resistor. When the cross-sectional area of the resistor is increased, the electrical resistance value is correspondingly reduced. Therefore, by the manner mentioned above, the purpose of reducing the electrical resistance value of the gate electrode layer 3 can be realized. Moreover, the gate wire designed by this manner can not only satisfy in-plane designs of large-sized circuits, but also does not affect optical transmittance rates of products.

The advantage of the present disclosure is that in the present disclosure, the data wire and the gate wire are set as parallel connection at a set location, and in a situation of not affecting a channel width of the active layer, the protruding sections are disposed in a spaced-apart manner on the original gate wire to reduce resistance of the gate wire, thereby effectively preventing the problem of excessive resistance of the gate wire due to overly large sizes of products, thus improving performance of the products.

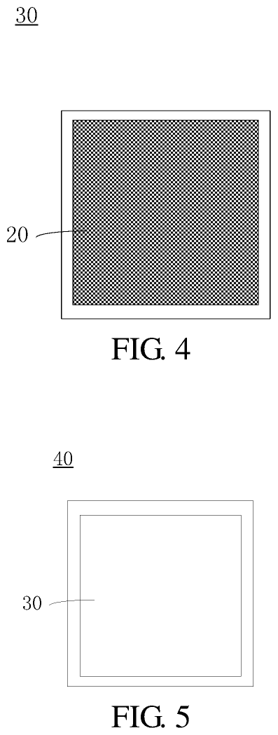

As illustrated in FIG. 4, an embodiment of the present disclosure further provides a display panel 30. The display panel includes the array substrate 20 of any embodiment mentioned above.

As illustrated in FIG. 5, an embodiment of the present disclosure further provides a display device 40. The display device 40 includes the display panel 30 mentioned above. The display device 40 includes the display panel 30 of embodiments mentioned above. The display device 40 can be any products or components having display functions, such as mobile phones, tablet PCs, televisions, display devices, laptops, digital photo frames, global positioning systems, and the like.

In summary, although the present disclosure has disclosed the preferred embodiments as above, however the above-mentioned preferred embodiments are not to limit to the present disclosure. A person skilled in the art can make any change and modification, therefore the scope of protection of the present disclosure is subject to the scope defined by the claims.

1. An array substrate, comprising a wiring region and a thin film transistor (TFT) device functional region; wherein the wiring region comprises:
a gate electrode layer;
a dielectric layer disposed on the gate electrode layer; and
a data wire layer disposed on the dielectric layer;
wherein a plurality of via holes are disposed on the dielectric layer, the data wire layer is connected to the gate electrode layer through the plurality of via holes, and a data wire formed from the data wire layer and a gate wire formed from the gate electrode layer constitute a parallel connection structure at positions of the plurality of via holes.

2. The array substrate as claimed in claim 1, wherein a plurality of protruding sections are formed on the data wire layer, the plurality of protruding sections are connected to a first gate electrode layer of the gate electrode layer through the plurality of via holes, and the plurality of protruding sections protrude from the first gate electrode layer along a width direction of the first gate electrode layer.

3. The array substrate as claimed in claim 2, wherein a region where each of the protruding sections is located corresponds to a region where each of the via holes is located.

4. The array substrate as claimed in claim 2, wherein a distance of the plurality of protruding sections protruding from the first gate electrode layer is not greater than 15 μm.

5. The array substrate as claimed in claim 1, wherein a resistance value of the parallel connection structure is less than a resistance value of the gate wire.

6. The array substrate as claimed in claim 1, wherein the TFT device functional region comprises a source electrode layer, a drain electrode layer, and an active layer, and the active layer is disposed under the gate electrode layer.

7. The array substrate as claimed in claim 6, wherein a vertical projection of the plurality of via holes on the gate electrode layer and a vertical projection of the source electrode layer and the drain electrode layer on the gate electrode layer are spaced apart.

8. A display panel, comprising the array substrate as claimed in claim 1.

9. A display device, comprising the display panel as claimed in claim 8.

10. The display device as claimed in claim 9, wherein a plurality of protruding sections are formed on the data wire layer, the plurality of protruding sections are connected to a first gate electrode layer of the gate electrode layer through the plurality of via holes, the plurality of protruding sections protrude from the first gate electrode layer along a width direction of the first gate electrode layer; a region where each of the protruding sections is located corresponds to a region where each of the via holes is located; a distance of the plurality of protruding sections protruding from the first gate electrode layer is not greater than 15 μm.
